(19) United States
(12) Patent Application Publication
(10) Pub. No.: US 2009/0080250 A1
(43) Pub. Date: Mar. 26, 2009

(54) NONVOLATILE SEMICONDUCTOR STORAGE DEVICE AND OPERATION METHOD THEREOF

(76) Inventors: Kiyohito NISHIHARA, Yokohama-shi (JP); Fumitaka ARAI, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/211,947

(22) Filed: Sep. 17, 2008

(30) Foreign Application Priority Data
Sep. 20, 2007 (JP) 2007-244321

(51) Int. Cl. G11C 16/06; H01L 29/788; G11C 16/00

(52) U.S. Cl. 365/185.03; 365/185.18; 257/314; 257/E29.3

(57) ABSTRACT

A multi-valued nonvolatile semiconductor storage device and an operation method thereof capable of setting a plurality of positive levels having positive threshold voltages and a plurality of negative levels having negative threshold voltages for storing information in a charge storage layer is provided. According to one aspect, there is provided a nonvolatile semiconductor storage device which comprises a storage element provided on a first surface of a semiconductor layer and including a charge storage layer provided with a plurality of positive levels having positive threshold voltages and a plurality of negative levels having negative threshold voltages to store information, and a back electrode provided on a second surface of the semiconductor layer to be opposite to the storage element, the back electrode being configured to apply a voltage which converts information stored in the negative level of the charge storage layer to information having a positive threshold voltage.

### CROSS-REFERENCE TO RELATED APPLICATIONS

This application is based upon and claims the benefit of priority from prior Japanese Patent Application No. 2007-244321, filed Sep. 20, 2007, the entire contents of which are incorporated herein by reference.

### BACKGROUND OF THE INVENTION

1. Field of the Invention

The present invention relates to a nonvolatile semiconductor storage device and an operation method thereof, and more particularly, it relates to a nonvolatile semiconductor device including a charge storage layer and an operation method thereof.

2. Description of the Related Art

A value-multiplication technique is effective in increasing the capacity of a nonvolatile semiconductor storage device such as a flash memory. However, this value-multiplication technique is facing various problems in connection with miniaturization in device sizes. For example, the problems include deterioration in the S-factor of a memory cell transistor due to shorter channels, interference between adjacent memory cells, deterioration in reliability, variations in a threshold voltage due to processing dimension variations, etc. In setting multi-valued levels, it is necessary to set the multi-valued levels in such a manner as to ensure that data in each level can be identified.

In the conventional value-multiplication technique, n-type memory cell transistors may be provided so that, for example, one of the multi-valued levels may have a threshold voltage (Vth) of 0 V or less (negative) and the rest of the multi-valued levels may have positive Vths between 0 V and a read voltage (Vread). In such a configuration, for example, there are three positive multi-valued levels in the case of four values, and seven positive multi-valued levels in the case of eight values. In order to set a large number of positive multi-valued levels in the range of up to operating voltages of the conventional technique, it is necessary to control so that a Vth variation width (Vth distribution) of the respective levels is to be narrow. However, in a flash memory configured by small memory cell transistors with undesirable S-factors, it is not easy to make the Vth variation width narrow after writing. In an actual write operation, a verify write is performed to set a predetermined Vth. However, a large Vth variation leads to an increase in write time due to an increase in the time for verification operation, which might adversely affect the achievement of a write speed required in the market. On the other hand, if the range of the Vths on the respective levels to set data is further extended to a positive side, it is possible to achieve a multi-valued level setting which includes high Vth levels while maintaining secure level intervals necessary to identify the data on the respective multi-valued levels even when the Vth variation width after writing is larger. However, this case inevitably leads to the necessity of operating with a high read voltage (Vread), which might deteriorate read disturb characteristics. Furthermore, in order to cope with the deterioration of the S-factor of a miniaturized cell, the interference between adjacent cells, and the deterioration of a data retention characteristic, the level intervals have to be wider to assure a margin for Vth variations. In this respect as well, the problem of the read disturb arises as in the above-mentioned case.

A semiconductor storage device capable of suppressing the deterioration of the read disturb characteristics has been disclosed in Jpn. Pat. Appln. KOKAI Publication No. 11-145312. In that semiconductor storage device, one memory cell comprises a first transistor having a charge storage layer provided on a first surface of a semiconductor layer, and a second transistor of a MISFET structure provided on a second surface of the semiconductor layer to be opposite to the first transistor. The first and second transistors share a diffusion layer. The second transistor of an unselected cell is turned on in reading data. This relaxes an electric field applied to a gate insulating film (tunnel insulating film) of the first transistor of the unselected cell, and thereby suppressing the deterioration of the read disturbance characteristics.

Furthermore, effects on a cell characteristic due to processing variations are more prominent in the miniaturized cells. If characteristic variations in the individual memory cell transistors are larger, the verification operation time for controlling the memory cell transistors at a predetermined threshold voltage increases, which increases the write time. The multi-valued flash memory is essential for survival in the flash memory market with fiercely dropping prices, but is not easy from the perspective of assuring the operation characteristic of the semiconductor device and maintaining its reliability as described above.

### BRIEF SUMMARY OF THE INVENTION

According to one aspect of the present invention, there is provided a nonvolatile semiconductor storage device which comprises: a storage element provided on a first surface of a semiconductor layer and including a charge storage layer provided with a plurality of positive levels having positive threshold voltages and a plurality of negative levels having negative threshold voltages to store information; and a back electrode provided on a second surface of the semiconductor layer to be opposite to the storage element, the back electrode being configured to apply a voltage which converts information stored in the negative level of the charge storage layer to information having a positive threshold voltage.

According to another aspect of the present invention, there is provided a method of operating a nonvolatile semiconductor storage device equipped with a storage element provided on a first surface of a semiconductor layer and including a charge storage layer and a control electrode, and a back electrode provided on a second surface of the semiconductor layer to be opposite to the storage element, the method comprises: storing information in one of a plurality of levels having negative threshold voltages in the charge storage layer; applying a voltage to the back electrode to convert information having the negative threshold voltages to information having positive threshold voltages; and reading the converted information.

### BRIEF DESCRIPTION OF THE SEVERAL VIEWS OF THE DRAWING

FIG. 1 shows one example of a nonvolatile semiconductor device according to a first embodiment of the present invention;

FIG. 2 is one example of an Id-Vg curve of the nonvolatile semiconductor device according to the first embodiment and showing the change of a Vth caused by application of a back gate voltage;

FIG. 3 shows one example of a Vth distribution of data write levels having negative Vths according to the first embodiment;

FIG. 4A shows one example of multi-valued levels having positive and negative Vths according to the first embodiment;

FIG. 4B is a diagram explaining the multi-valued levels having the negative Vths after raising to positive Vths; and

FIG. 5 is a diagram showing one example of a nonvolatile semiconductor device according to a second embodiment of the present invention.

### DETAILED DESCRIPTION OF THE INVENTION

Embodiments of the present invention provide a multi-valued nonvolatile semiconductor storage device and an operation method thereof capable of setting a plurality of positive levels having positive threshold voltages and a plurality of negative levels having negative threshold voltages for storing information in a charge storage layer. More particularly, embodiments of the present invention provide a multi-valued nonvolatile semiconductor storage device including a plurality of positive and negative levels in a charge storage layer for storing information while maintaining reliability and operation performance in a miniaturized cell in which there arise problems of S-factor deterioration, interference between adjacent cells, reliability deterioration and processing variations, and an operation method thereof.

The nonvolatile semiconductor storage device according to the embodiments of the present invention is a silicon on insulator (SOI) type nonvolatile semiconductor storage device comprising back gate electrodes, and includes a plurality of negative levels having negative threshold voltages (Vth) and a plurality of positive levels having positive Vths in a charge storage portion such as a floating gate electrode. In a reading operation, a voltage is applied to the back gate electrodes to raise the negative Vths to positive Vths, such that negative Vth information stored in the negative levels is converted to apparently positive Vth information, thereby enabling the negative Vth information to be read with a positive read voltage indirectly. This allows the setting of a plurality of negative levels having negative Vths in addition to a plurality of positive levels having positive Vths, and makes it possible to increase the number of multi-valued levels while maintaining reliability and operation performance. This enables higher integration of the nonvolatile semiconductor storage device.

The embodiments of the present invention will be described with reference to the accompanying drawings. The accompanying drawings, which are incorporated in and constitute a part of the specification, illustrate embodiments of the invention, and together with the general description given above and the detailed description of the embodiments given below, serve to explain principles of the invention. Throughout the drawings, corresponding portions are denoted by corresponding reference numerals. The embodiments are only examples, and various changes and modifications can be made without departing from the scope and spirit.

A value-multiplication technique is required to realize the nonvolatile semiconductor storage device with higher integration. The value-multiplication technique needs to satisfy reliability even if number of the multi-valued levels are increased, regardless of the S-factor deterioration, the interference between adjacent cells, the reliability deterioration, the processing variations, etc. that become problems in a miniaturized cell. For example, in a conventional NAND flash memory using enhancement-type n-type memory cell transistors, a plurality of levels having positive Vths are provided. The following three options are generally conceived as measures for further value multiplication of the NAND flash memory: (1) additional multi-valued levels are provided on levels ranging higher positive Vths, (2) a narrower Vths width of the respective levels is set to increase multi-valued levels without raising the read voltage (Vread), (3) a plurality of negative multi-valued levels having negative Vths are provided in addition to a plurality of positive multi-valued levels.

However, the options of (1) and (2) are not realistic solutions in that the above-mentioned reliability deterioration and increase of write time are not inevitable in miniaturized cells. The option (3) enables new levels to be provided with no problem even in a miniaturized cell in which there arise problems of the S-factor deterioration, the interference between adjacent cells, the reliability deterioration, the processing variations, etc. However, if data having negative Vths is to be read in a prior art reading scheme, a negative voltage is applied to a control gate electrode, so that it is necessary to apply both positive and negative voltages to the control gate electrode in accordance with the multi-valued levels having positive Vths and negative Vths. Moreover, the voltage resistant design of wells of peripheral transistors also has to be redesigned to adapt to the application of the negative gate voltage, and not only the structures of the wells but also peripheral circuits have to be drastically changed. Therefore, the option (3) is not a realistic solution either in terms of device designing in the prior art reading scheme.

However, if the information having a negative Vth is converted to information having an apparently positive Vth and thus can be read even indirectly in the option (3), the application of the negative control gate voltage in reading can be avoided. Thus, the miniaturized cells can be used the increased multi-valued levels without any measures for the characteristic variations due to the S-factor deterioration, the interference between adjacent cells, the reliability deterioration, the processing variations, etc. The conversion of the information having a negative Vth to the information having an apparently positive Vth can be achieved by the SOI type nonvolatile semiconductor storage device, for example, a NAND flash memory, equipped with the back gate electrodes. The nonvolatile semiconductor storage device and the operation method thereof according to the embodiments of the present invention will be described below.

### First Embodiment

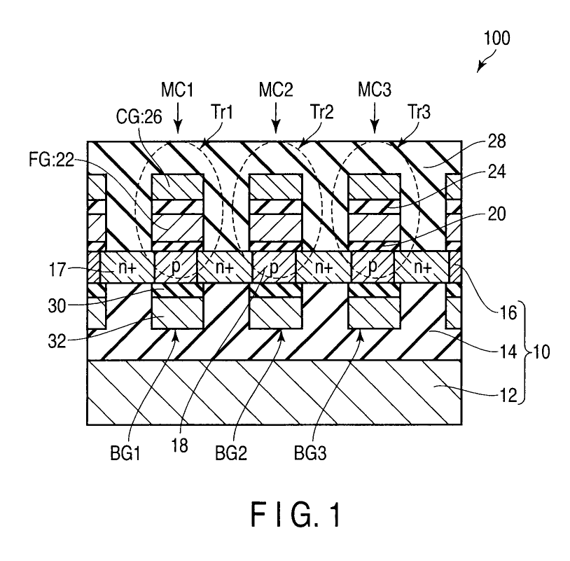

One example of a nonvolatile semiconductor device 100 according to a first embodiment of the present invention is shown in FIG. 1. In the diagram, there are shown adjacent three memory cells MC1 to MC3 of a NAND memory cell array having a plurality of (enhancement-type) NAND memory cells connected in series. The number of memory cells contained in one memory cell array is, for example, 8, 16, 32 or 64. The nonvolatile semiconductor storage device according to the present embodiment uses what is called a silicon on insulator (SOI) substrate 10 in which a semiconductor (SOI) layer 16 is provided on a buried insulating film (buried oxide (BOX)) layer 14 on a semiconductor substrate 12. The SOI layer 16 has a thickness of, for example, about 5 to 100 nm, and is made of, for example, single crystal silicon or polycrystalline silicon.

One memory cell MC includes a memory cell transistor Tr provided on a first surface of the SOI layer 16, and a back gate electrode BG provided opposite to the memory cell transistor Tr in an insulating film, for example, the BOX film 14 on a second surface of the SOI layer 16. The memory cell transistor Tr comprises a gate stack including a first electrode 22 provided on a first surface of the SOI layer 16 on a first insulating film 20 and a second electrode 26 provided on the first electrode 22 interposing a second insulating film 24 therebetween. The gate stack is covered with an interlayer insulating film 28. The first electrode 22 stores charges and functions as a charge storage layer such as a floating gate electrode. The second electrode 26 functions as a control gate electrode. Materials that can be used for the first and second gate electrodes 22, 24 are, for example, aluminum (Al), copper (Cu), platinum (Pt), gold (Au), silver (Ag), tungsten (W), nickel (Ni), cobalt (Co), titanium (Ti), tantalum (Ta), polycrystalline silicon, and silicides of the above-mentioned metals.

A third electrode 32 is provided, on a third insulating film 30, on the second surface of the SOI layer 16 opposite to each gate stack. The third electrode 32 functions as a back gate electrode BG. The third insulating film 30 is, for example, a silicon oxide (SiO₂) film having a thickness of, for example, about 4 to 100 nm. Materials that can be used for the third electrode 32 are, for example, the above-mentioned materials including Al, Cu, Pt, Au, Ag, W, Ni, Co, Ti, Ta, polycrystalline silicon, and silicides of the above-mentioned metals. The thickness of the third electrode 32 is, for example, about 10 to 1000 nm. The distance between the third electrode 32 and the semiconductor substrate 12 is, for example, about 30 to 100 nm, and these are insulated from each other by the BOX layer 14.

The SOI layer 16 is provided with a first semiconductor region 17 having a first conductivity type and a second semiconductor region 18 having a second conductivity type. The second semiconductor region 18 is located immediately under each gate stack, and serves as a channel region. The first semiconductor region 17 is shown in FIG. 1 so that it is formed over the entire thickness of the SOI layer 16, but it does not necessarily have to be formed over the entire thickness. When the memory cell transistor Tr is, for example, an enhancement-type n-channel transistor, the first conductivity type is an n-type, and the second conductivity type is a p-type.

Next, an operation scheme is described using the enhancement-type n-channel nonvolatile semiconductor storage device according to the present embodiment as an example. Described here are methods characterizing the present embodiment: a reading method which converts (raises) information having a negative Vth in the memory cell transistor Tr to information having an apparently positive Vth, and a method of writing into one of the negative multi-valued levels.

(1) Method of Reading Negative Vth

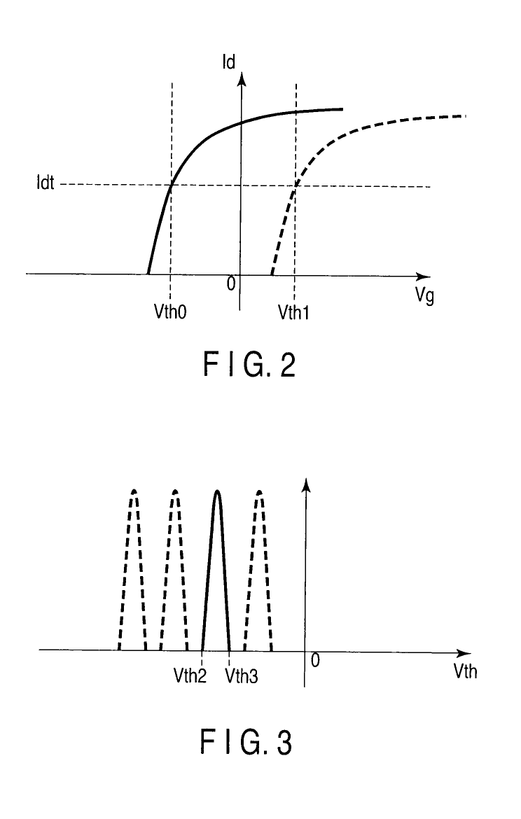

An example of operation is described wherein the second memory cell MC2 in FIG. 1 is selected. A solid line in FIG. 2 is an Id-Vg curve of the memory cell transistor Tr2 in the case where the Vth of Tr2 is negative when a back gate electrode BG2 is in a floating state. Since Tr2 is an enhancement type, a condition in which Tr2 has a negative Vth is a condition in which positive charges such as holes are stored in the floating gate electrode FG2(22) of Tr2. Here, a threshold voltage Vth is defined as Vg where Id=Idr. The threshold voltage of Tr2 at this point is Vth=Vth0.

(a) First, a control gate voltage Vg of Tr2 is set at 0 V to determine whether the Vth of Tr2 is positive or negative as in the conventional operation.

(b) When it is determined that Vth0<0, the Id-Vg curve is shifted to the positive direction of the Vg to cause the Vth of Tr2 to be positive. That is, an appropriate negative back gate bias (back gate voltage Vbg<0 V) is applied to the back gate electrode BG2 opposite to Tr2. At this point, in the unselected cells (MC1, MC3), voltages that turn on channels of their transistors Tr1, Tr3 are applied to the back gate electrodes and/or the control gate electrodes. For example, back gate electrodes BG1, BG3 of the unselected cells are floating or fixed to 0 V, and the control gate voltage is set to Vread of about +5 V.

The negative voltage applied to the back gate electrode BG2 has to be limited in the range of an electric field of the third insulating film 30 equal to or less than about 5 MeV/cm at which the third insulating film 30 does not cause Fowler-Nordheim (FN) tunneling. For example, if the third insulating film 30 is an SiO₂ film having a thickness of 10 nm, the back gate voltage Vbg desirably ranges from 0 to −5 V. A broken line shown in FIG. 2 is one example of the Id-Vg curve when a negative back gate bias (Vbg<0 V) is applied to BG2, and the Vth of Tr2 is raised to a positive Vth1. The back gate bias to be applied is set to a suitable constant value, so that the negative Vth0 correspond to the raised positive Vth1 one to one.

(c) Reading is performed while the back gate voltage Vbg is being applied to BG2, and the positive Vth1 in one-to-one relation with the negative Vth0 is read. It is thus possible to indirectly recognize the level of the negative Vth0 of Tr2.

(2) Method of Writing Negative Vth

(a) A case is considered where the Vth of the memory cell transistor Tr2 is set in the range of one of the multi-valued levels having negative Vths, for example, Vth=Vth2 to Vth3 (Vth2<Vth<Vth3<0) assuming a negative multi-valued level, as shown in FIG. 3. First, operation is performed to control an amount of electric charge in the floating gate electrode FG2(22) so that the threshold voltage of Tr2 is a negative Vth. That is, as in erasure operation of a conventional NAND flash memory, a voltage of 0 V is applied to a control gate electrode CG2(26) of Tr2, and a voltage of about +15 to +23 V is applied to the SOI layer 16, so that electrons in the floating gate electrode FG2(22) are pulled out into the SOI layer 16, and moreover, positive charges such as holes are injected into the floating gate electrode FG2(22).

(b) After the operation of (a), a predetermined back gate bias Vbg is applied to the back gate electrode BG2 to indirectly read the Vth of Tr2 as a positive Vth′, in accordance with the technique described in the reading method of (1). If it is determined that Vth>Vth3, then more holes need to be injected into the FG2(22), and the operation of (a) and reading are repeatedly carried out until Vth<Vth3.

(c) After it has been determined that Vth<Vth3, Vth>Vth2 is checked. If Vth<Vth2, the holes have been overly injected into the FG2(22), so that 0 V is once applied to the SOI layer 16 and a voltage of, for example, +15 to +23 V is applied to the control gate electrode CG2(26) to perform writing. After the operations of (a) and (b) have been performed, reading is again performed to check whether Vth>Vth2.

(d) The operations of (a) to (c) are repeated until predetermined Vth2<Vth<Vth3 is reached.

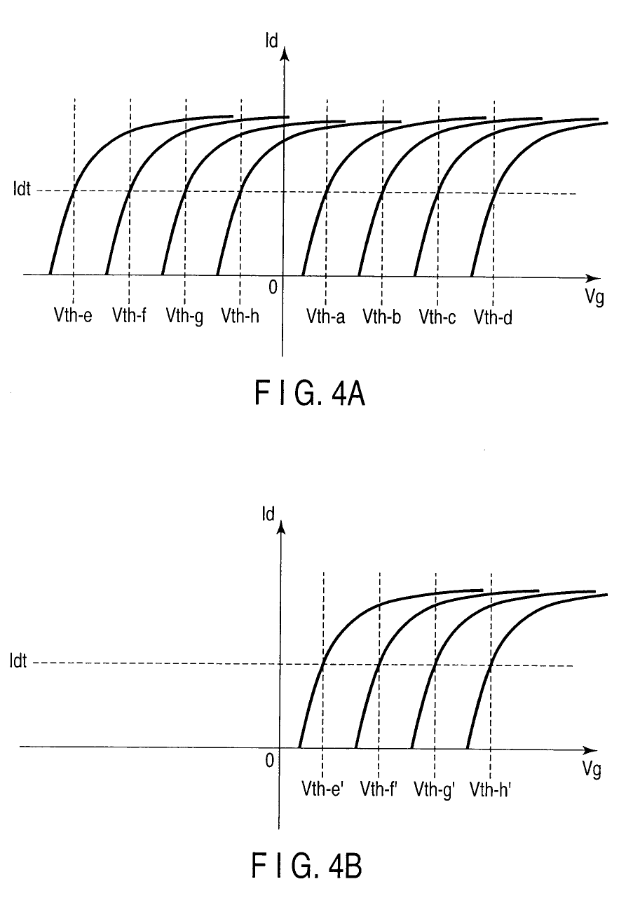

In this way, one memory cell can serve as an eight-valued memory cell in which four negative multi-valued levels (Vth-e, Vth-f, Vth-g, Vth-h) are set in addition to four positive multi-valued levels (Vth-a, Vth-b, Vth-c, Vth-d) as shown in, for example, the Id-Vg curves in FIG. 4A. However, a negative high value of a Vth leads to severe read disturb, so that the value of the negative Vth is desirably limited to about −5 V.

These negative Vths can be raised to positive Vth's as shown in FIG. 4B by applying the appropriate back gate bias Vbg of a predetermined constant value as described in the reading method (1), so that four negative levels (Vth-e, Vth-f, Vth-g, Vth-h) can be read as four positive levels (Vth-e′, Vth-f′, Vth-g′, Vth-h′) that correspond one to one, respectively.

As has been described so far, the present embodiment makes it possible to realize a multi-valued nonvolatile semiconductor storage device and an operation method thereof capable of setting a plurality of negative levels having negative Vths in addition to the conventional plurality of positive levels having positive Vths in order to store information, without narrowing the control range of the Vths of the respective multi-valued levels and without increasing the read voltage (Vread).

### Second Embodiment

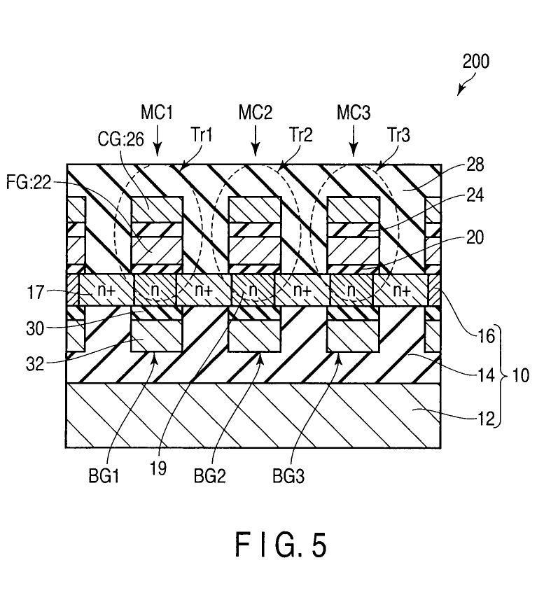

One example of a depression-type nonvolatile semiconductor device 200 according to a second embodiment of the present invention is shown in FIG. 5. In the diagram, there are shown adjacent three memory cells MC1 to MC3 of a NAND memory cell array in which a plurality of NAND memory cells are connected. Each of the memory cells MC includes a memory cell transistor Tr provided on a first surface of an SOI layer 16, and a back gate electrode BG(32) provided opposite to the memory cell transistor Tr in an insulating film, for example, a BOX film 14 on a second surface of the SOI layer 16. The difference between this device and the enhancement-type nonvolatile semiconductor storage device 100 according to the first embodiment is that a third semiconductor region 19 serving as a channel region located immediately under a gate stack is the same first conductivity type, for example, n-type as a first semiconductor region 17. The first and third semiconductor regions are formed over the entire thickness of the SOI layer 16, and may be different or the same in dopant concentration. The structure of the semiconductor storage device is the same as that in the first embodiment in other respects and is therefore not described in detail.

In the case of a depression-type transistor, when no charge is injected into a floating gate electrode (FG(22)), a channel is always on and Vth is a negative value if a control gate voltage Vg is 0 V.

Next, an operation scheme of the nonvolatile semiconductor storage device according to the present embodiment is described.

(1) Method of Reading Negative Vth

An example of operation is described wherein the second memory cell MC2 in FIG. 5 is selected. The Id-Vg characteristics are described with reference to FIG. 2. The solid line in FIG. 2 is an Id-Vg curve of the memory cell transistor Tr2 in the case where the Vth of Tr2 is negative when a back gate electrode BG2 is in a floating state.

(a) First, the control gate voltage Vg of Tr2 is set at 0 V to determine whether the Vth of Tr2 is positive or negative as in the conventional operation.

(b) When it is determined that Vth0<0, the Id-Vg curve is shifted to the positive direction of the Vg to cause the Vth of Tr2 to be positive. Specifically, since Tr2 is a depression-type transistor, a negative back gate bias (back gate voltage Vbg<0 V) for rendering the Vth of Tr2 positive is applied to the back gate electrode BG2. This Vbg has the same polarity as in the first embodiment. At this point, in the unselected cells (MC1, MC3), voltages that turn on channels of their transistors Tr1, Tr3 are applied to the back gate electrodes and/or the control gate electrodes. For example, back gate electrodes BG1, BG3 of the unselected cells are floating or fixed to 0 V, and the control gate voltage is set to a Vread voltage of about +5 V. The negative voltage applied to the back gate electrode BG2 has to be limited in the range of an electric field of the third insulating film 30 equal to or less than about 5 MeV/cm at which the third insulating film 30 does not cause Fowler-Nordheim (FN) tunneling. In the present embodiment as well, as in the broken line shown in FIG. 2, by applying a negative back gate bias (Vbg<0 V) to BG2, the Id-Vg curve of Tr2 is raised to have a positive Vth. That is, as in the first embodiment, the Vth of Tr2 is raised from a negative Vth0 to a positive Vth1. By applying the appropriate back gate bias having a constant value, the negative Vth0 and the positive Vth1 correspond one to one.

(c) Reading is performed while the negative back gate voltage Vbg is being applied to BG2, and the positive Vth1 in one-to-one relation with the negative Vth0 is read, such that the level of the negative Vth0 of Tr2 can be indirectly recognized.

(2) Method of Writing Negative Vth

(a) A case is considered where the Vth of the memory cell transistor Tr2 is set in the range of one of the multi-valued levels having negative Vths, for example, Vth=Vth2 to Vth3 (Vth2<Vth<Vth3<0) assuming a negative multi-valued level, as shown in FIG. 3. A depression-type transistor may have a negative Vth even when a small amount of electron is stored in the floating gate electrode FG2(22), so that whether the threshold voltage of Tr2 is higher or lower than a predetermined Vth (Vth2<Vth<Vth3) is first determined by the technique described in the reading method of (1). That is, the negative back gate bias Vbg is applied to the back gate electrode BG2 to indirectly read the Vth of Tr2 as a positive Vth′. If it is determined that Vth<Vth2, process is proceed to (d).

(b) If it is determined that Vth>Vth3, a voltage of about 0 V is applied to a control gate electrode CG2(26) of Tr2, and a voltage of about +15 to +23 V is applied to the SOI layer 16, and then electrons in the floating gate electrode FG2(22) are pulled out into the SOI layer 16, or a positive charge (holes) is injected into the floating gate electrode FG2(22), as in erasure operation of a conventional NAND flash memory.

(c) After the operation of (b), the Vth is evaluated again by the technique described in the reading method of (1). If it is determined that Vth>Vth3, it is necessary to further pull out the electrons in the floating gate electrode FG2(22) or inject holes into the FG2(22), and the operation of (b) and reading are repeatedly carried out until Vth<Vth3.

(d) After it has been determined that Vth<Vth3, Vth>Vth2 is checked. If Vth<Vth2, the electrons have been overly pulled out or the holes have been overly injected into the FG2(22), so that 0 V is once applied to the SOI layer 16 and a voltage of, for example, +15 to +23 V is applied to the control gate electrode CG2(26) to perform writing. After the operations of (b) and (c) have been performed, reading is again performed to check whether Vth>Vth2.

(e) The operations of (b) to (d) are repeated until predetermined Vth2<Vth<Vth3 is reached.

Thus, as in the first embodiment, one memory cell can serve as an eight-valued memory cell in which four negative multi-valued levels (Vth-e, Vth-f, Vth-g, Vth-h) are set in addition to four positive multi-valued levels (Vth-a, Vth-b, Vth-c, Vth-d) as shown in the Id-Vg curve in FIG. 4A, for example.

As has been described so far, the present embodiment makes it possible to realize a multi-valued nonvolatile semiconductor storage device and an operation method thereof capable of setting a plurality of negative levels having negative Vths in addition to the conventional plurality of positive levels having positive Vths, without narrowing the control range of the Vths of the respective multi-valued levels and without increasing the read voltage (Vread).

Although the nonvolatile semiconductor storage device having the floating gate electrodes in which the multi-valued levels are respectively set for the positive Vths and the negative Vths has been described by way of example in the above embodiments, the present invention is also applicable to, for example, a metal-oxide-nitride-oxide-semiconductor (MONOS) type nonvolatile semiconductor storage device which stores a charge in a dielectric film instead of the floating gate electrode.

As described above, an appropriate predetermined back gate bias is applied during reading to raise the negative Vth to a positive Vth, and negative Vth information is converted to apparently positive Vth information without applying a negative voltage to the control gate electrode, thereby enabling the negative Vth information to be indirectly read with the positive voltage of the control gate electrode, and setting a plurality of negative multi-valued levels having negative Vths. Here, the introduction of the back gate electrodes increases costs due to the increase of processes and the addition of control circuits, but multi-valued levels can be increased without difficulty in terms of device designing, and a cost reduction can be made in the end.

Such a nonvolatile semiconductor storage device with a plurality of positive levels having positive Vths and a plurality of negative levels having negative Vths for storing information enables value multiplication with no need to increase a read voltage or narrowing the distribution width of the Vths of the respective multi-valued levels. Consequently, it is possible to realize a multi-valued nonvolatile semiconductor storage device capable of miniaturizing cells and easing the restriction in reliability.

As described above, according to a plurality of embodiments of the present invention, it is possible to provide a multi-valued nonvolatile semiconductor storage device and an operation method thereof capable of setting a plurality of positive levels having positive threshold voltages and a plurality of negative levels having negative threshold voltages for storing information.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A nonvolatile semiconductor storage device comprising:
a storage element provided on a first surface of a semiconductor layer and including a charge storage layer provided with a plurality of positive levels having positive threshold voltages and a plurality of negative levels having negative threshold voltages to store information; and
a back electrode provided on a second surface of the semiconductor layer to be opposite to the storage element, the back electrode being configured to apply a voltage which converts information stored in the negative level of the charge storage layer to information having a positive threshold voltage.

2. The nonvolatile semiconductor storage device according to claim 1, wherein a plurality of storage elements are electrically connected in series on the semiconductor layer.

3. The nonvolatile semiconductor storage device according to claim 1, wherein the semiconductor layer is a semiconductor layer provided on a semiconductor substrate interposing part of a buried insulating film therebetween.

4. The nonvolatile semiconductor storage device according to claim 3, wherein the back electrode is provided within the buried insulating film.

5. The nonvolatile semiconductor storage device according to claim 1, wherein the storage element includes a first electrode provided on a first insulating film on the semiconductor layer, and a second electrode provided on a second insulating film on the first electrode.

6. The nonvolatile semiconductor storage device according to claim 1, wherein the voltage for the conversion is a negative voltage.

7. The nonvolatile semiconductor storage device according to claim 1, wherein each level of the plurality of positive levels contains different amount of negative charges each other, and each level of the plurality of negative levels contains different amount of positive charges each other.

8. The nonvolatile semiconductor storage device according to claim 1, wherein the semiconductor layer includes a first region of a first conductivity type interposed between the storage element and the back electrode, and a second region of a second conductivity type which is not provided with the storage element.

9. The nonvolatile semiconductor storage device according to claim 8, wherein the first conductivity type is a p-type, and the second conductivity type is an n-type.

10. The nonvolatile semiconductor storage device according to claim 1, wherein the semiconductor layer includes a first region of a predetermined conductivity type interposed between the storage element and the back electrode, and a second region of the same conductivity type which is not provided with the storage element.

11. A method of operating a nonvolatile semiconductor storage device equipped with a storage element provided on a first surface of a semiconductor layer and including a charge storage layer and a control electrode, and a back electrode provided on a second surface of the semiconductor layer to be opposite to the storage element, the method comprising:
storing information in one of a plurality of levels having negative threshold voltages in the charge storage layer;
applying a voltage to the back electrode to convert information having the negative threshold voltages to information having positive threshold voltages; and
reading the converted information.

12. The method according to claim 11, wherein storing the information in different level of the plurality of levels having the negative threshold voltages is controlled by applying a positive voltage to the semiconductor layer to inject different amount of positive charges into the charge storage layer.

13. The method according to claim 11, wherein the converting information is converting the negative threshold voltages of the storage element to corresponding positive threshold voltages.

14. The method according to claim 11, wherein the charge storage layer includes a plurality of positive levels having positive threshold voltages and a plurality of negative levels having negative threshold voltages to store information.

15. The method according to claim 14, wherein storing the information in the plurality of levels having the positive threshold voltages includes storing negative charges into the charge storage layer.

16. The method according to claim 11, wherein the plurality of storage elements are enhancement-type n-channel transistors,
storing the information in the plurality of levels having the negative threshold voltages is storing positive charges into the charge storage layer, and
converting the information is applying a negative voltage of a predetermined value to the back electrode.

17. The method according to claim 16, wherein reading the converted information includes applying the negative voltage of the predetermined value to the back electrode and reading a voltage of the control electrode at which a current of a predetermined value flows in the semiconductor layer.

18. The method according to claim 11, wherein the plurality of storage elements are depression-type n-channel transistors, and converting the information is applying a negative voltage of a predetermined value to the back electrode.
